(19) United States
(12) Patent Application Publication
(10) Pub. No.: US 2008/0105962 A1
(43) Pub. Date: May 8, 2008

(54) CHIP PACKAGE

(75) Inventors: Yu-Lin Lee, Kaohsiung County (TW); Gwo-Liang Weng, Kaohsiung City (TW)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 11/833,716

(22) Filed: Aug. 3, 2007

(30) Foreign Application Priority Data
Nov. 8, 2006 (TW) 95141280

(51) Int. Cl. H01L 23/02

(52) U.S. Cl. 257/686; 257/E23.172

(57) ABSTRACT

A chip package and a process thereof are provided. The chip package includes a first package unit and a second package unit. The first package unit includes a carrier; a chip, disposed on the carrier and electrically connected thereto; a first encapsulant, disposed on the carrier and covering the chip; an interposer, disposed on the first encapsulant, having a plurality of pads thereon, and electrically connected to the carrier; a plurality of conducting elements, respectively disposed on the pads; and a second encapsulant, covering the surface of the carrier, encapsulating the chip, the first encapsulant, the interposer, and the conducting elements, and exposing the top of each conducting element. The second package unit is disposed on the first package unit, and electrically connected to the interposer through the conducting elements.

### CROSS-REFERENCE TO RELATED APPLICATION

This application claims the priority benefit of Taiwan application serial no. 95141280, filed on Nov. 8, 2006. All disclosure of the Taiwan application is incorporated herein by reference.

### BACKGROUND OF THE INVENTION

1. Field of the Invention

The present invention relates to a semiconductor device package and a process thereof. More particularly, the present invention relates to a stacked type chip package and a process thereof.

2. Description of Related Art

In current high information society, the multi-media market is expanding rapidly. Thus, the integrated circuit (IC) package technology should be developed following the trends of digitization, network, regional connection, and humanization design of electronic devices. In order to meet the above requirements, various aspects, such as high-speed processing, multi-function, integration, miniaturization and light weight, and low price of an electronic element must be strengthened, and thereby the IC package technology is developed towards microminiaturization and high density. Besides common ball grid array (BGA) package, chip-scale package (CSP), flip chip package (F/C package) in the conventional art, a stacked type chip package technology has been proposed recently, in which a plurality of chip package units is stacked to increase the overall package density.

FIG. 1 is a schematic sectional view of a conventional stacked type chip package. Referring to FIG. 1, the conventional stacked type chip package 100 includes a first package unit 110, a second package unit 120, and a plurality of solder balls 130. The solder balls 130 are disposed in the periphery of a chip 114 of the first package unit 110, so as to connect the first package unit 110 and the second package unit 120. However, as the solder balls 130 are disposed in the periphery of the chip 114, the available area of the circuit substrate 112 is occupied, and thus the volume of the stacked type chip package 100 cannot be further reduced. Further, the chip 114 is connected to the circuit substrate 112 through wire bonding, and an encapsulant 118 is formed on a local area of the circuit substrate 112, so as to cover the chip 114 and conducting wires 116. As such, it is disadvantageous for the design of the encapsulating mold. That is, the encapsulating mold must be designed according to the size and position of the encapsulant 118, and cannot be used in processes of package units with different sizes.

FIG. 2 is a schematic sectional view of another conventional stacked type chip package. Referring to FIG. 2, the stacked type chip package 200 is similar to the stacked type chip package 100 in FIG. 1, except that the encapsulant 212 of the first package unit 210 of the stacked type chip package 200 covers the entire circuit substrate 216, and exposes a plurality of solder balls 214 disposed on the circuit substrate 216 and surrounding a chip 218. The second package unit 220 is fixed above the first package unit 210, and electrically connected to the first package unit 210 through solder balls 230 and the solder balls 214.

The encapsulant 212 of FIG. 2 covers the entire circuit substrate 216, and such design can improve the compatibility of the encapsulating mold. However, as the solder balls 214 and the solder balls 230 are still disposed in the periphery of the chip 218, the available area of the circuit substrate 216 is also occupied, thus limiting the size of the stacked type chip package 200.

FIG. 3 is a schematic sectional view of still another conventional stacked type chip package. Referring to FIG. 3, in the stacked type chip package 300, a circuit substrate 312b is disposed on the first package unit 310, and the circuit substrate 312b is electrically connected to the circuit substrate 312a of the first package unit 310 through the conducting wires 316. Moreover, the second package unit 320 is connected to the circuit substrate 312b through a plurality of solder balls 330, such that the first package unit 310 is electrically connected to the second package unit 320 through the circuit substrate 312b. Such design can solve the problem of taking up the space of the circuit substrate 312a to dispose the solder balls. However, as an encapsulant 318 of a particular shape should be formed to encapsulate the conducting wires 316 and expose the surface of the circuit substrate 312b for disposing the solder balls 330, the problem that the encapsulating mold cannot be shared still exists, and different encapsulating molds must be designed according to the profile of the package unit.

### SUMMARY OF THE INVENTION

The present invention is directed to providing a stacked type chip package, for eliminating the disadvantages in the conventional chip package technology.

The present invention is also directed to a chip package, which can be applied to the stacked type chip package to solve the problem existing in the conventional chip package technology.

The present invention is further directed to a chip package process, for fabricating the chip package.

As embodied and broadly described herein, a chip package including a carrier, a chip, a first encapsulant, an interposer, a plurality of conducting elements, and a second encapsulant is provided. The carrier has a carrying surface and a back surface opposite to the carrying surface. The chip is disposed on the carrying surface and electrically connected to the carrier. The first encapsulant is disposed on the carrying surface and covering the chip. The interposer is disposed on the first encapsulant and electrically connected to the carrier, wherein a plurality of pads is disposed on a surface of the interposer. The conducting elements are respectively disposed on the pads. The second encapsulant covers the carrying surface, encapsulates the chip, the first encapsulant, the interposer, and the conducting elements, and exposes the top of each conducting element.

The present invention further provides a stacked type chip package mainly formed by stacking the above chip package as a package unit with another package unit. The two package units are electrically connected to each other through the conducting elements and the interposer.

According to an embodiment of the present invention, the carrier or the interposer is, for example, a circuit substrate.

According to an embodiment of the present invention, the first package unit further includes a plurality of conducting bumps, and the chip is electrically connected to the carrier through the conducting bumps by means of flip chip.

According to an embodiment of the present invention, the first package unit further includes a plurality of first conducting wires connected between the chip and the carrier and encapsulated by the first encapsulant.

According to an embodiment of the present invention, the first package unit further includes a plurality of second conducting wires connected between the interposer and the carrier and encapsulated by the second encapsulant.

According to an embodiment of the present invention, the conducting elements are, for example, a plurality of first solder balls. Further, the pads on the interposer are, for example, arranged in an array, and accordingly, the second package unit is a BGA package unit or other package devices having array leads.

According to an embodiment of the present invention, the first package unit further includes a plurality of second solder balls disposed on the back surface of the carrier. The second solder balls are electrically connected to the chip and the interposer through the carrier.

A chip package process is further provided. First, a carrier is provided, in which the carrier has a carrying surface and a back surface opposite to the carrying surface. Then, a chip is disposed on the carrying surface, and electrically connected thereto. After that, a first encapsulant is formed on the carrying surface to cover the chip. Then, an interposer is disposed on the first encapsulant, wherein a plurality of pads is disposed on a surface of the interposer. Subsequently, a plurality of conducting elements is disposed on the pads. Afterwards, the interposer is electrically connected to the carrier. Thereafter, a second encapsulant is covered on the carrying surface, so as to encapsulate the chip, the first encapsulant, the interposer, and the conducting elements, and expose the top of each conducting element.

According to an embodiment of the present invention, the chip is electrically connected to the carrier through, for example, a flip chip bonding process or wire bonding process.

According to an embodiment of the present invention, the step of disposing the conducting elements is, for example, disposing one first solder ball on each pad.

According to an embodiment of the present invention, the chip package process further includes disposing a plurality of second solder balls on the back surface of the carrier, such that the second solder balls are electrically connected to the chip and the interposer through the carrier.

According to an embodiment of the present invention, the chip package process further includes disposing a second package unit on the first package unit, such that the second package unit is electrically connected to the interposer through the conducting elements, so as to form a stacked type chip package.

In view of the above, according to the present invention, the interposer is disposed above the chip to connect the two package units, so the available space of the carrier of the package unit is saved, thus enhancing the integration of the stacked type chip package. In addition, as the encapsulant covers the entire carrying surface of the carrier, and the profile of the encapsulant may not be affected by the size and configuration of the chip, the encapsulating mold used in the chip package process of the present invention is applicable to different chip sizes and configurations.

In order to make the aforementioned and other objectives, features, and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic sectional view of a conventional stacked type chip package.

FIG. 2 is a schematic sectional view of another conventional stacked type chip package.

FIG. 3 is a schematic sectional view of still another conventional stacked type chip package.

FIG. 4 is a schematic sectional view of a chip package according to an embodiment of the present invention.

FIG. 5 is a schematic cross-sectional view of a stacked type chip package according to an embodiment of the present invention.

FIGS. 6A-6I show a process flow of fabricating the chip package.

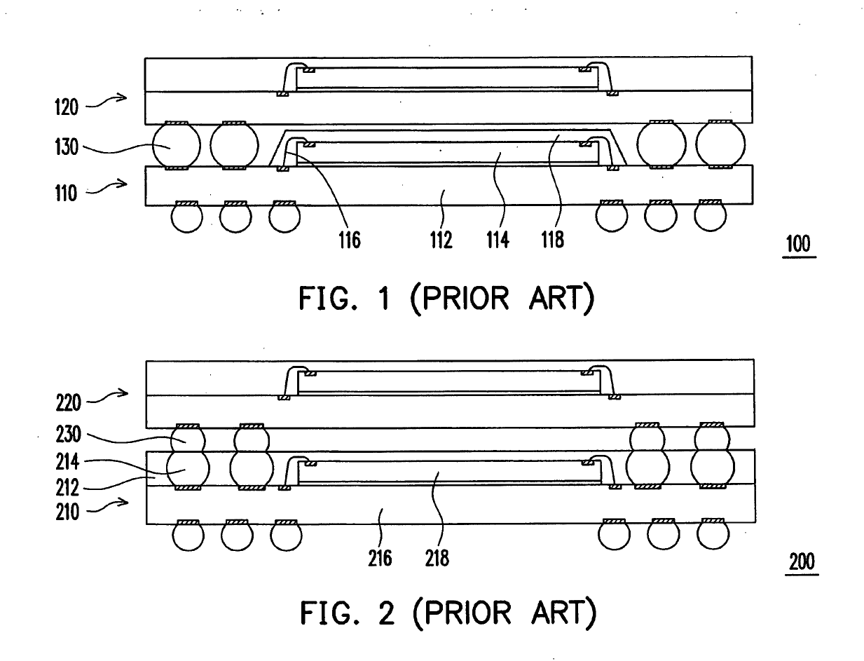

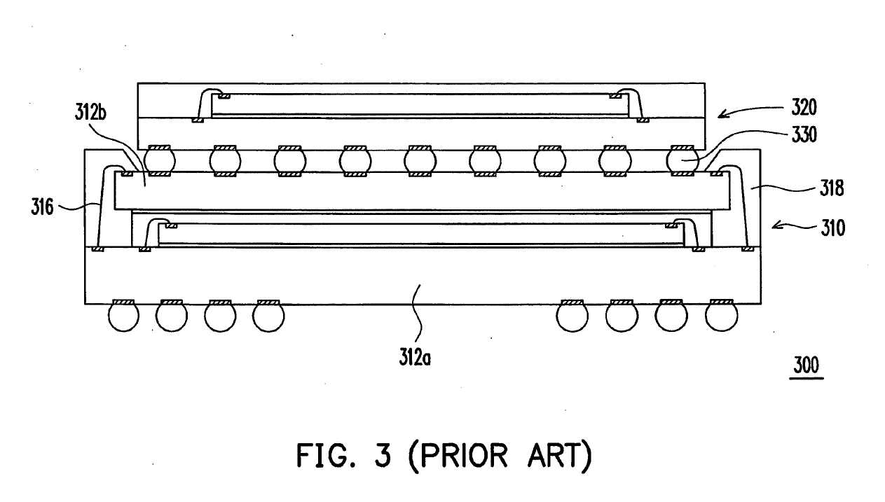

### DESCRIPTION OF EMBODIMENTS

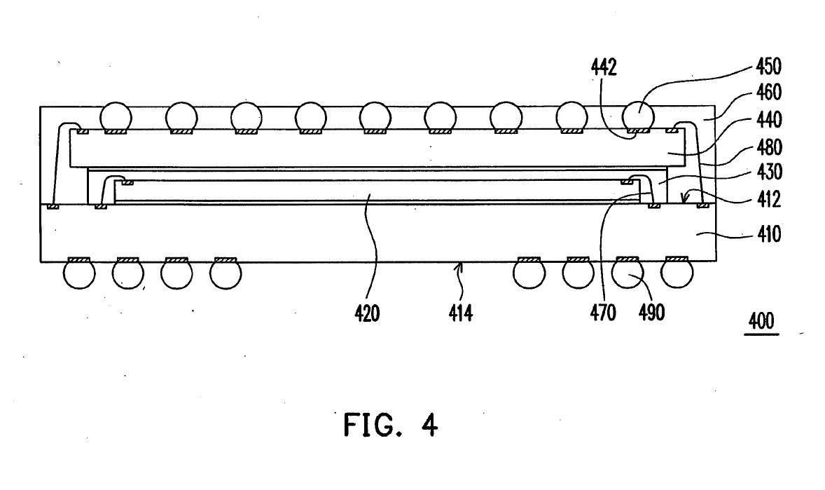

FIG. 4 is a schematic sectional view of a chip package according to an embodiment of the present invention. Referring to FIG. 4, the chip package 400 of this embodiment includes a carrier 410, a chip 420, a first encapsulant 430, a interposer 440, a plurality of conducting elements 450, and a second encapsulant 460. The carrier 410 has a carrying surface 412 and a back surface 414 opposite to the carrying surface 412. The chip 420 is disposed on the carrying surface 412, and electrically connected to the carrier 410. The first encapsulant 430 is disposed on the carrying surface 412, and covers the chip 420. The interposer 440 is disposed on the first encapsulant 430, and electrically connected to the carrier 410, wherein the interposer 440 has a plurality of pads 442 thereon. The conducting elements 450 are respectively disposed on the pads 442. The second encapsulant 460 covers the carrying surface 412, encapsulates the chip 420, the first encapsulant 430, the interposer 440, and the conducting elements 450, and exposes the top of each conducting element 450.

In this embodiment, the interposer 440 and the carrier 410 can be a circuit substrate or a printed circuit board (PCB), respectively. However, the configurations of the interposer 440 and the carrier 410 are not limited in the present invention. In other embodiments, the interposer 440 can also be another package device capable of providing a plurality of pads 442 above the surface of the first encapsulant 430. The carrier 410 can also be another package device suitable for carrying the chip 420. Additionally, in this embodiment, the conducting elements 450 are, for example, solder balls. However, in other embodiments of the present invention, the conducting elements 450 can also be conducting blocks or other conductors.

In view of the above, as the chip package 400 of this embodiment utilizes the interposer 440 disposed above the chip 420 to gather the conducting elements 450 electrically connected to the outside above the chip 420, it is advantageous for saving the available area on the carrier 410. Thus, the integration of the chip package 400 is improved, and the carrier 410 has a sufficient carrying area to carry a chip 420 of a large size. Further, in this embodiment, the second encapsulant 460 of the chip package 400 covers the entire carrying surface 412, and the profile of the second encapsulant 460 may not be affected by the size and configuration of the chip 420, so the encapsulant mould for forming the second encapsulant 460 is applicable to chips 420 of various sizes and configurations. That is, a single encapsulant mould can be used to fabricate a chip package 400 of different specifications, and thus there is no need to customize various encapsulant moulds according to the specifications, such that the fabrication cost of the chip package 400 is reduced.

In this embodiment, the chip 420 is electrically connected to the carrier 410 through a plurality of first conducting wires 470 by means of wire bonding, and the first conducting wires 470 are encapsulated by the first encapsulant 430. However, in another embodiment of the present invention, the chip 420 is electrically connected to the carrier 410 through a plurality of conducting bumps (not shown) by means of flip chip. Further, in this embodiment, the interposer 440 is electrically connected to the carrier 410 through a plurality of second conducting wires 480 by means of wire bonding, and the second conducting wires 480 are encapsulated by the second encapsulant 460.

In this embodiment, the pads 442 are disposed in an array on the upper surface of the interposer 440. However, in other embodiments of the present invention, the pads 442 are disposed in other manners above the surface of the first encapsulant 430. Moreover, the chip package 400 further includes a plurality of solder balls 490 disposed on the back surface 414 of the carrier 410. The solder balls 490 are electrically connected to the chip 420 and the interposer 440 through the carrier 410, and the chip package 400 is electrically connected to other electronic components (for example, motherboard) through the solder balls 490.

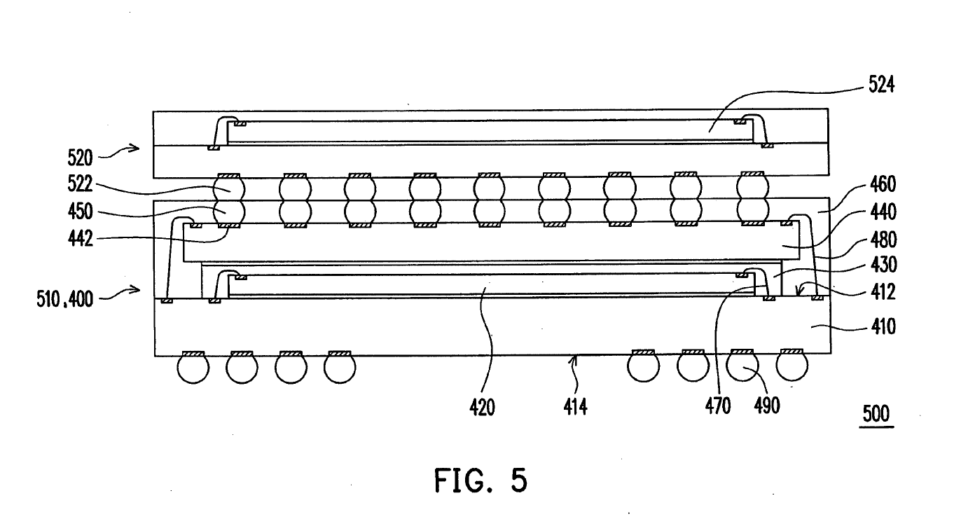

The present invention further provides a stacked type chip package mainly formed by stacking the aforementioned chip package as a package unit with another package unit. FIG. 5 is a schematic cross-sectional view of a stacked type chip package according to an embodiment of the present invention. Referring to FIG. 5, the stacked type chip package 500 of this embodiment includes a first package unit 510 and a second package unit 520. The first package unit 510 is the aforementioned chip package 400. The second package unit 520 is disposed on the first package unit 510, and electrically connected to the interposer 440 through the conducting elements 450. Particularly, in this embodiment, the second package unit 520 is a BGA package unit, and spherical leads 522 of the second package unit 520 are correspondingly connected to the conducting elements 450 arranged in an array. In addition, the interposer 440 has sufficient area to dispose the conducting elements 450, so it is suitable for the bonding of the package units of high integration.

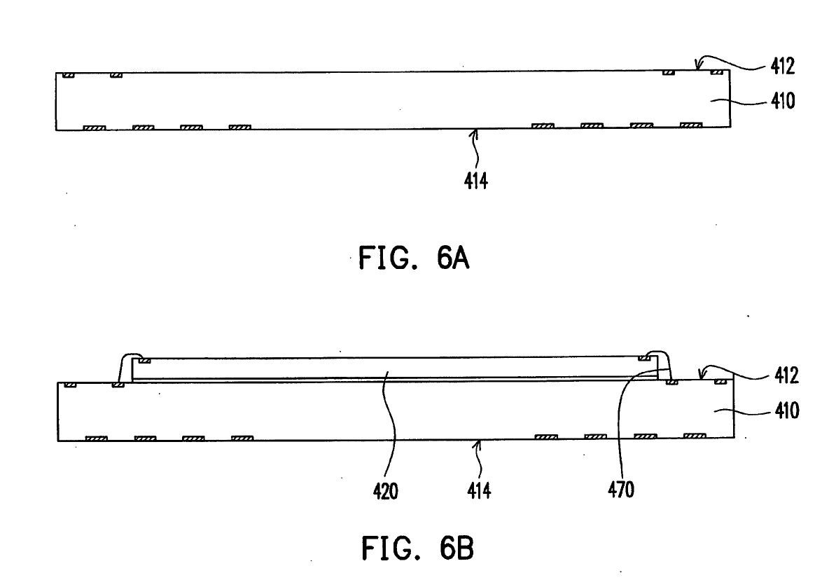

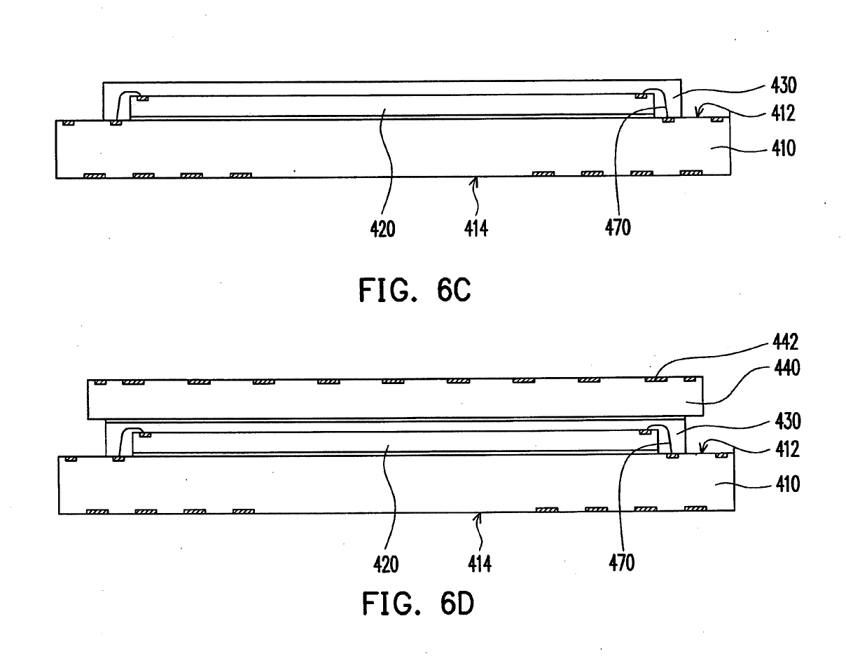

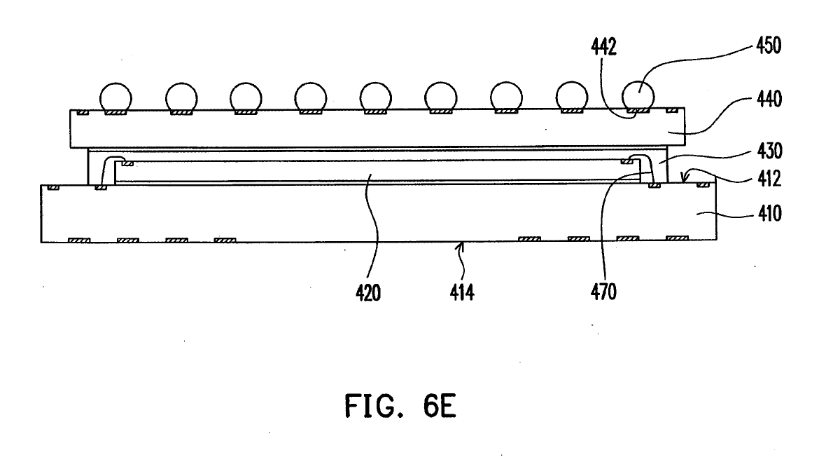

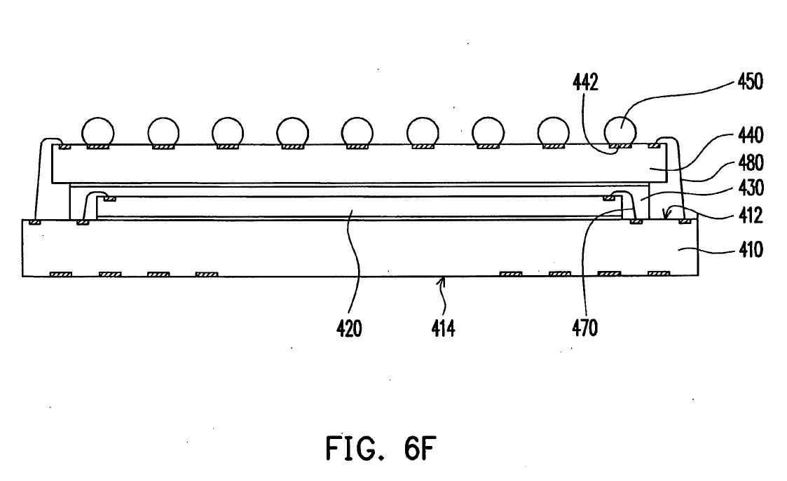

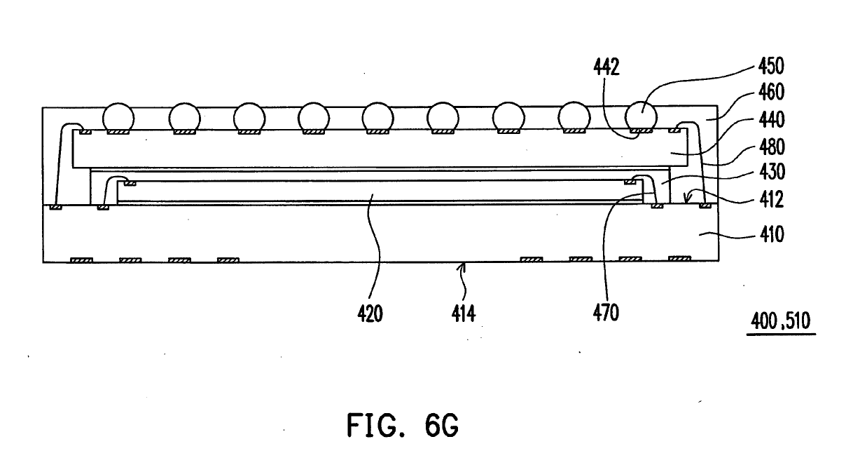

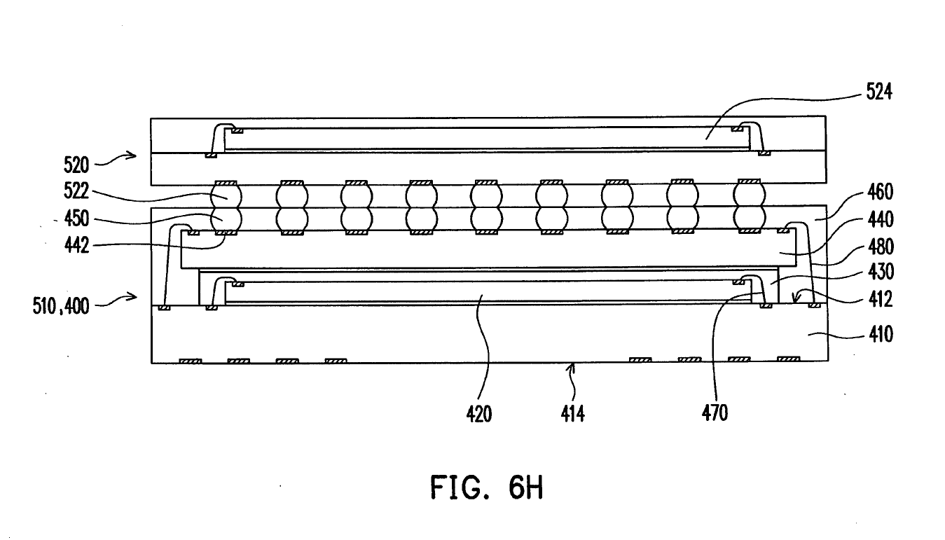

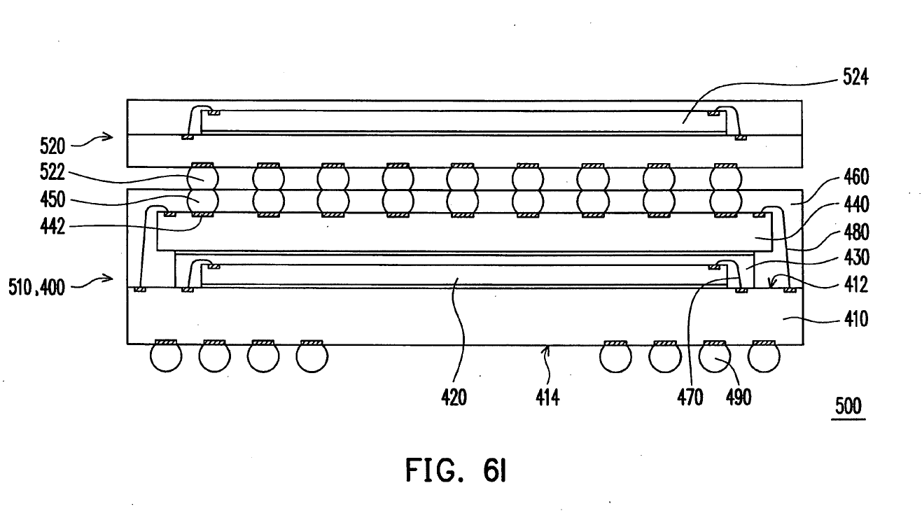

FIGS. 6A-6I show a process flow of fabricating the chip package. The process flow includes first providing the carrier 410, referring to FIG. 6A. Next, referring to FIG. 6B, the chip 420 is disposed on the carrying surface 412 of the carrier 410, and electrically connected thereto. In this embodiment, a wire bonding process is performed, such that the chip 420 is electrically connected to the carrier 410 through a plurality of first conducting wires 470. Definitely, according to other embodiments of the present invention, the chip 420 can be electrically connected to the carrier 410 through flip chip bonding or other manners.

Next, referring to FIG. 6C, the first encapsulant 430 is formed on the carrying surface 412 of the carrier 410, so as to cover the chip 420. For example, the first encapsulant 430 can be formed with an encapsulating mold. In this embodiment, the formed first encapsulant 430 further encapsulates the first conducting wires 470.

After that, referring to FIG. 6D, the interposer 440 is disposed on the first encapsulant 430, so as to provide a plurality of pads 442 above the surface of the first encapsulant 430. Next, referring to FIG. 6E, the conducting elements 450 are formed on the pads 442. Particularly, in this embodiment, one solder ball is disposed on each pad 442. However, according to other embodiments of the present invention, a conducting block or a conductor of other types can be formed on each pad 442.

Then, referring to FIG. 6F, the interposer 440 is electrically connected to the carrier 410. In this embodiment, for example, a wire bonding process is performed, such that the interposer 440 is electrically connected to the carrier 410 through the second conducting wires 480.

Thereafter, referring to FIG. 6G, the second encapsulant 460 covers the carrying surface 412 of the carrier 410, so as to encapsulate the chip 420, the first encapsulant 430, the interposer 440, and the conducting elements 450, and expose the top of each conducting element 450. For example, in this embodiment, the second encapsulant 460 is formed with an encapsulating mold. The second encapsulant 460 covers the entire carrying surface 412, so the profile of the second encapsulant 460 may not be affected by the size and configuration of the chip 420, so the encapsulating mold is applicable to chips 420 of different sizes and configurations, thus having a high process compatibility. Additionally, in this embodiment, the formed second encapsulant 460 also encapsulates the second conducting wires 480. Thereby, the fabrication of the chip package 400 or the first package unit 510 is finished.

The chip package process of this embodiment further includes the steps shown in FIGS. 6H-6I, so as to form a stacked type chip package. Afterwards, referring to FIG. 6H, the second package unit 520 is disposed on the first package unit 510, and electrically connected to the interposer 440 through the conducting elements 450. Next, referring to FIG. 6I, in this embodiment, optionally, a plurality of solder balls 490 is disposed on the back surface 414 of the carrier 410, and is electrically connected to the chip 420 and the interposer 440 through the carrier 410. Thereby, the fabrication of the stacked type chip package 500 is substantially finished.

In view of the above, according to the present invention, the interposer is disposed above the chip to connect the two package units, so the available space of the carrier in the package unit is saved, thus enhancing the integration of the stacked type chip package, and making the carrier have a sufficient carrying area to carry a chip of a large size. Further, the interposer has sufficient area to dispose a large number of conducting elements, which is advantageous for increasing the number of the leads of the package unit. In addition, as the stacked type chip package of the present invention adopts the design of using an encapsulant to cover the entire surface of the carrier, the profile of the encapsulant may not be affected by the size and configuration of the chip. In other words, the encapsulating mold used in the chip package process of the present invention is applicable to various chip package designs, thus having a high compatibility, which helps to save the manufacturing cost.

Though the present invention has been disclosed above by the preferred embodiments, they are not intended to limit the present invention. Anybody skilled in the art can make some modifications and variations without departing from the spirit and scope of the present invention. Therefore, the protecting range of the present invention falls in the appended claims.

What is claimed is:

1. A stacked type chip package, comprising:
a first package unit, comprising:
a carrier, having a carrying surface and a back surface opposite to the carrying surface;
a chip, disposed on the carrying surface, and electrically connected to the carrier;
a first encapsulant, disposed on the carrying surface, and covering the chip;
an interposer, disposed on the first encapsulant, and electrically connected to the carrier, wherein a plurality of pads is disposed on a surface of the interposer;
a plurality of conducting elements, respectively disposed on the pads;
a second encapsulant, covering the carrying surface, encapsulating the chip, the first encapsulant, the interposer, and the conducting elements, and exposing a top of each conducting element; and
a second package unit, disposed on the first package unit, and electrically connected to the interposer through the conducting elements.

2. The stacked type chip package as claimed in claim 1, wherein the carrier is a circuit substrate.

3. The stacked type chip package as claimed in claim 1, wherein the interposer is a circuit substrate.

4. The stacked type chip package as claimed in claim 1, wherein the first package unit further comprises a plurality of conducting bumps, and the chip is electrically connected to the carrier through the conducting bumps by means of flip chip.

5. The stacked type chip package as claimed in claim 1, wherein the first package unit further comprises a plurality of first conducting wires connected between the chip and the carrier and encapsulated by the first encapsulant.

6. The stacked type chip package as claimed in claim 1, wherein the first package unit further comprises a plurality of second conducting wires connected between the interposer and the carrier, and encapsulated by the second encapsulant.

7. The stacked type chip package as claimed in claim 1, wherein the conducting elements comprise a plurality of first solder balls.

8. The stacked type chip package as claimed in claim 1, wherein the pads are arranged in an array.

9. The stacked type chip package as claimed in claim 1, wherein the second package unit is a ball grid array (BGA) package unit.

10. The stacked type chip package as claimed in claim 1, wherein the first package unit further comprises a plurality of second solder balls disposed on the back surface of the carrier and electrically connected to the chip and interposer through the carrier.

11. A chip package, comprising:
a carrier, having a carrying surface and a back surface opposite to the carrying surface;
a chip, disposed on the carrying surface, and electrically connected to the carrier;
a first encapsulant, disposed on the carrying surface, and covering the chip;
an interposer, disposed on the first encapsulant, and electrically connected to the carrier, wherein a plurality of pads is disposed on a surface of the interposer;
a plurality of conducting elements, respectively disposed on the pads; and
a second encapsulant, covering the carrying surface, encapsulating the chip, the first encapsulant, the interposer, and the conducting elements, and exposing a top of each conducting element.

12. The chip package as claimed in claim 11, wherein the carrier is a circuit substrate.

13. The chip package as claimed in claim 11, wherein the interposer is a circuit substrate.

14. The chip package as claimed in claim 11, further comprising a plurality of conducting bumps, wherein the chip is electrically connected to the carrier through the conducting bumps by means of flip chip.

15. The chip package as claimed in claim 11, further comprising a plurality of first conducting wires connected between the chip and the carrier and encapsulated by the first encapsulant.

16. The chip package as claimed in claim 11, further comprising a plurality of second conducting wires connected between the interposer and the carrier and encapsulated by the second encapsulant.

17. The chip package as claimed in claim 11, wherein the conducting elements comprise a plurality of first solder balls.

18. The chip package as claimed in claim 11, wherein the pads are arranged in an array.

19. The chip package as claimed in claim 11, further comprising a plurality of second solder balls disposed on the back surface of the carrier, and electrically connected to the chip and the interposer through the carrier.
